(19) United States
(12) Patent Application Publication
(10) Pub. No.: US 2018/0045515 A1
(43) Pub. Date: Feb. 15, 2018

(54) MICROMECHANICAL SENSOR CORE FOR AN INERTIAL SENSOR

(71) Applicant: Robert Bosch GmbH, Stuttgart (DE)

(72) Inventors: Barbara Simoni, Dettlingen An Der Erms (DE); Christian Hoeppner, Stuttgart (DE); Denis Gugel, Pliezhausen (DE); Guenther-Nino-Carlo Ullrich, Reutlingen (DE); Sebastian Guenther, Tuebingen (DE); Timm Hoehr, Reutlingen (DE); Johannes Seelhorst, Pfullingen (DE)

(21) Appl. No.: 15/671,235

(22) Filed: Aug. 8, 2017

(30) Foreign Application Priority Data
Aug. 11, 2016 (DE) 102016214962.8

(51) Int. Cl. G01C 19/5733; G01P 15/14; B81B 3/00; G01P 15/125

(52) U.S. Cl. CPC G01C 19/5733; G01P 15/125; G01P 15/14; B81B 3/0078; B81B 2201/0228

(57) ABSTRACT

A micromechanical sensor core for an inertial sensor, having a movable seismic mass, a defined number of anchor elements, by which the seismic mass is fastened on a substrate, a defined number of stop devices fastened on the substrate for stopping the seismic mass, a first springy stop element, a second springy stop element and a solid stop element being developed on the stop device. The stop elements are designed in such a way that the seismic mass is able to strike in succession against the first springy stop element, the second springy stop element and the solid stop element.

### CROSS REFERENCE

The present application claims the benefit under 35 U.S.C. § 119 of German Patent Application No. DE 102016214962.8 filed on Aug. 11, 2016, which is expressly incorporated herein by reference in its entirety.

### FIELD

The present invention relates to a micromechanical sensor core for an inertial sensor. The present invention furthermore relates to a method for producing a micromechanical sensor core for an inertial sensor.

### BACKGROUND INFORMATION

Micromechanical inertial sensors in the form of acceleration sensors are limited in their freedom of motion by stop elements. One task of the stop elements is above all to minimize the kinetic energy acting on the inertial sensor, which a moving mass of the inertial sensor has when it touches solid electrodes of the inertial sensors at an elevated acceleration. This makes it possible to minimize damage to the mentioned solid electrodes.

German Patent Application No. DE 10 2013 222 747 A1 describes a micromechanical Z sensor, which with the aid of at least two spatially separated absorbing devices per rocker arm is able better to distribute an impact energy of the rocker of the micromechanical Z sensor and thus provide efficient protection of the rocker against breakage.

### SUMMARY

One object of the present invention is to provide an improved micromechanical sensor core for an inertial sensor.

According to a first aspect of the present invention, the object may be achieved by a micromechanical sensor core for an inertial sensor, having:
a movable seismic mass;
a defined number of anchor elements, by which the seismic mass is fastened on a substrate;
a defined number of stop devices fastened on the substrate for stopping the seismic mass;
a first springy stop element, a second springy stop element and a solid stop element being developed on the stop device;
the stop elements being designed in such a way that the seismic mass is successively able to strike the first springy stop element, the second springy stop element and the solid stop element.

This advantageously supports the cancellation of an adhesive effect between the seismic mass and the stop elements due to a return force of the springy stop elements in the event of an excessive application of force, whereby the seismic mass is in effect “pushed back” into its designated original position. By way of the second springy stop element, an optimization of a total application of force of the two springy stop elements is achieved. Advantageously, the first springy stop element may be markedly relieved by the second springy stop element.

This provides a cascading stop structure for the micromechanical sensor core of an inertial sensor, which is advantageously able to reduce an adhesive effect. This advantageously achieves an improved robustness of the micromechanical inertial sensor with respect to overload.

According to a second aspect of the present invention, the object is achieved by a method for producing a micromechanical sensor core for an inertial sensor, including the following steps:
providing a substrate;
providing a movable seismic mass;
anchoring the seismic mass on the substrate using anchor elements;
providing a defined number of stop devices for stopping the seismic mass;
developing a first springy stop element, a second springy stop element and a solid stop element on every stop device, the stop elements being designed in such a way that in the event of an impact, the seismic mass first strikes the first springy stop element, thereupon the second springy stop element and thereupon the solid stop element.

Preferable further developments of the micromechanical inertial sensor are the subject matter of dependent claims.

One advantageous development of the micromechanical sensor core includes that a stiffness of the second springy stop element is greater by a defined measure than a stiffness of the first springy stop element. This supports the achievement of a cascading stop behavior of the two springy stop elements.

Another advantageous development of the micromechanical sensor core includes that per stop device, respectively two springy first stop elements, two springy second stop elements and two solid stop elements are developed symmetrically with respect to the seismic mass. This advantageously supports a better distribution of the application of force on the stop elements.

Another advantageous development of the micromechanical sensor core includes that two stop devices are provided, which are developed symmetrically with respect to the seismic mass. The symmetrical arrangement of the stop devices in relation to the seismic mass promotes an operating characteristic of an inertial sensor having the micromechanical sensor core that is as uniform as possible.

The present invention is described below in detail with additional features and advantages with reference to several figures. The figures are intended in particular to illustrate the features of the invention and are not necessarily drawn to scale. Identical or functionally identical elements have the same reference numerals. For the purpose of greater clarity, it may be provided that not all reference numerals are indicated in all figures.

Disclosed device features result analogously from corresponding disclosed method features and vice versa. This means in particular that features, technical advantages and embodiments relating to the method for producing a micromechanical sensor core for an inertial sensor result analogously from corresponding embodiments, features and advantages relating to the micromechanical sensor core for an inertial sensor and vice versa.

### BRIEF DESCRIPTION OF THE DRAWINGS

FIG. 1 shows a top view of a conventional micromechanical sensor core for an inertial sensor.

FIG. 2 shows a section from the top view of FIG. 1.

FIG. 3 shows a detailed view of a specific embodiment of a proposed micromechanical sensor core.

FIG. 4 shows a top view of a specific embodiment of a proposed micromechanical sensor core.

FIG. 5 shows a basic sequence of a specific embodiment of a method for producing a micromechanical sensor core for an inertial sensor.

FIG. 6 shows a block diagram of an inertial sensor with a specific embodiment of the proposed micromechanical sensor core.

### DETAILED DESCRIPTION OF EXAMPLE EMBODIMENTS

Stop elements for micromechanical inertial sensors may be developed as solid or as springy structures. Springy stop elements have in particular the following two functions:
By their deformation, they contribute to the reduction of the critical energy.
By their return force, they are able to release the micromechanical inertial sensor from an “adhesive” or “hooked” state.

A difficulty in designing the mentioned springy stop elements lies in their correct dimensioning. A stop element that is too soft cannot fulfill its functions since it is able to absorb hardly any mechanical energy and only has a small return force. A stop element that is too hard effectively acts as a solid stop and in this manner also cannot fulfill its functions.

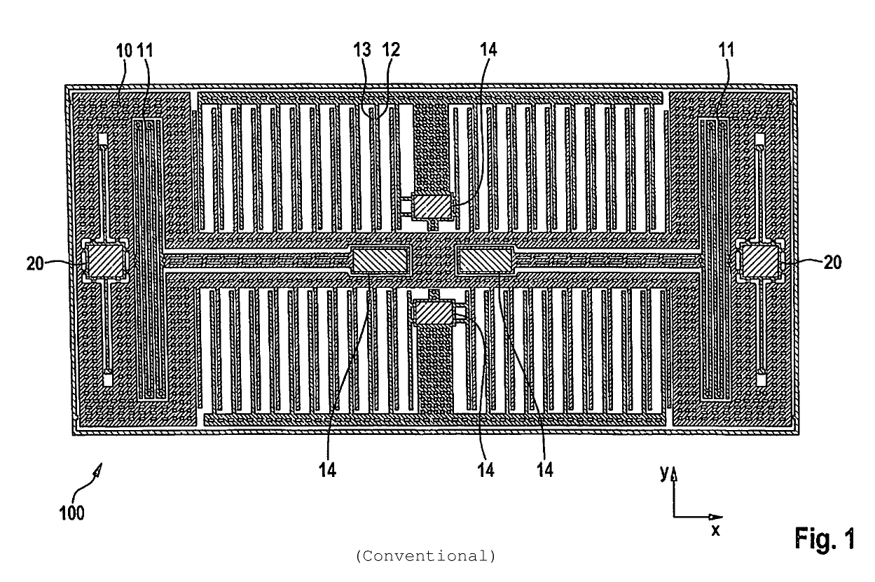

FIG. 1 shows a top view of a conventional micromechanical sensor core 100 for a micromechanical in-plane inertial sensor, which detects accelerations in the xy plane. Sensor core 100 is developed as a spring-mass system having a movable perforated seismic mass 10 and anchor elements 14, which achieve a connection of seismic mass 10 to a substrate (“mainland”) situated below it. It may be seen that seismic mass 10 is supported in movable fashion via spring elements 11. It may further be seen that there are electrodes 12, 13 developed on the seismic mass, which interact with fixed counterelectrodes (not shown) and in this manner detect accelerations of seismic mass 10 in the xy plane in the x direction.

It may be seen that four anchor elements 14 are anchored on the substrate symmetrically and centrally with respect to seismic mass 10. The purpose of this is above all to prevent a bending of the substrate situated below seismic mass 10 from being detected by the inertial sensor, as much as possible. This may be substantiated by the fact that due to the central arrangement of the four anchor elements 14, a bending of the substrate hardly affects an area of the substrate in the area of anchor elements 14.

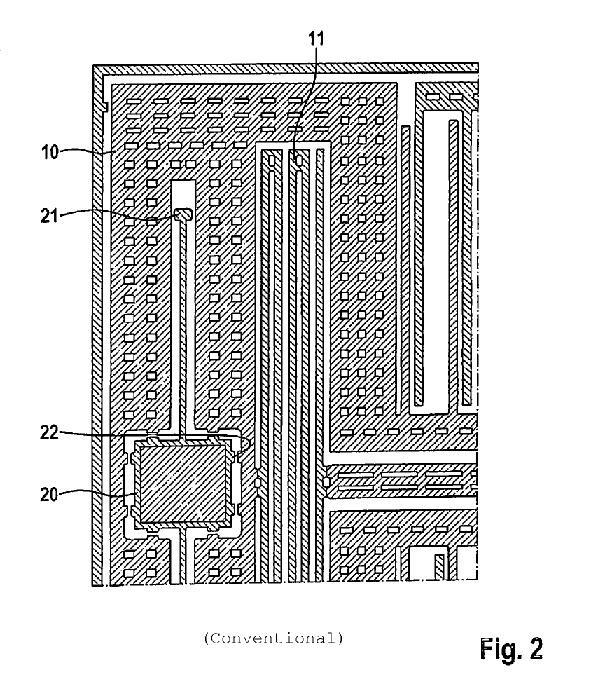

FIG. 2 shows an enlarged section of micromechanical sensor core 100 from FIG. 1. A first springy stop element 21 may be seen, which is developed on stop device 20 and which has an elongated bar, which achieves a springy or elastic or flexible spring structure for the first springy stop element 21. At the end of the bar, a head region having a greater diameter than the bar is developed, which is provided for impacts on seismic mass 10. For this purpose, a distance between the head region and the seismic mass is suitably dimensioned.

Furthermore, a solid stop element 22 may be seen that is also developed on stop device 20. Solid stop element 22 is developed in knob-like fashion and in this manner forms a stiff stop element, which is spaced apart from movable seismic mass 10 in a defined manner.

Altogether two types of stop elements are thus provided, namely, first springy stop element 21, whose task it is to limit the movement of seismic mass 10 in the event of a mechanical overload. First springy stop element 21 is flexible, and, in the event of a mechanical overload of the inertial sensor (e.g., when a mobile terminal device strikes the ground), is touched first by seismic mass 10, cushions it and limits its movement. In the event of an even greater overload, the bar of first springy stop element 21 bends all the way, as a result of which seismic mass 10 is subsequently blocked by solid stop elements 22. This is possible because the distances between seismic mass 10 and stop elements 21, 22 differ, a distance between first springy stop element 20 and seismic mass 10 being smaller by a defined measure than a distance between solid stop element 22 and seismic mass 10.

Altogether four springy first stop elements 21 are required in order to cancel the adhesive forces occurring at the atomic level, when seismic mass 10 makes contact with stop elements 21, 22, which are able to cause seismic mass 10 to adhere to stop elements 21, 22. The first springy stop elements 21 are able to aid in reducing this effect in that, when first springy stop elements 21 deflect and a spring force is thereby generated, they return seismic mass 10 into the original position.

The present invention provides an improvement of the conventional structure shown in FIGS. 1 and 2.

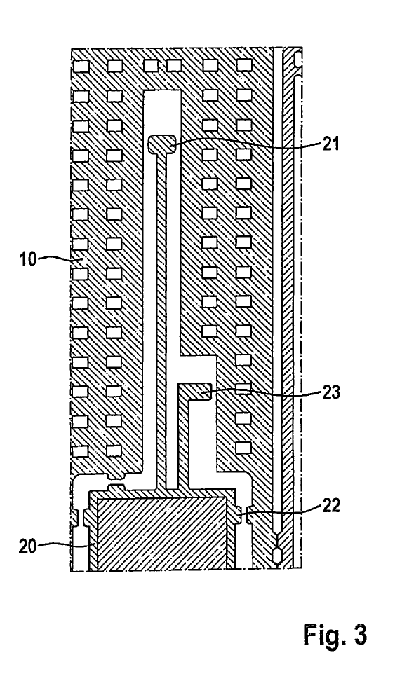

FIG. 3 shows a top view of a section of a specific embodiment of a proposed micromechanical sensor core 100. It may be seen that between the first springy stop element 21 and the solid stop element 22, a second springy stop element 23 is now situated, which distributes mechanical impact energy in the event of an impact of seismic mass 10. Second springy stop element 23 is likewise developed on stop device 20 and likewise has a bar, which in comparison to the bar of first springy stop element 21, however, is markedly shorter by a defined measure. Furthermore, second springy stop element 23 has a kind of hammer structure at its head, which is designed to strike against seismic mass 10 in the event of an impact.

Functionally, the present invention provides for seismic mass 10, in the event of a mechanical overload, to strike first against first springy stop element 21, thereupon against second springy stop element 23 and finally against solid stop element 22. The spring forces of the two springy stop elements 21, 23, which are activated in the process, free seismic mass 10 from an adhesive position even more efficiently compared to the conventional structure and push it back into the designated position of rest.

For this purpose, a distance between the first springy stop element 21 and seismic mass 10 is designed to be less than a distance between second springy stop element 23 and seismic mass 10. In addition, a distance of second springy stop element 23 from seismic mass 10 is designed to be less than a distance between solid stop element 22 and seismic mass 10.

As a result, it is thereby possible to achieve a sequential, cascading impact of seismic mass 10 against stop elements 21, 23 and 22.

Furthermore, the lengths of the bars of springy stop elements 21, 23 are also suitably dimensioned.

The sum of the spring force of springy stop elements 21, 23 is in this instance greater than an adhesive force between seismic mass 10 and stop elements 21, 22, 23, which causes the described release effect.

In effect, the present invention provides a spring structure, which allows for a cascading impact of seismic mass 10 against stop device 20. Advantageously, the stiffness of springy stop elements increases dynamically from the time at which first springy stop element 21 is contacted by seismic mass 10.

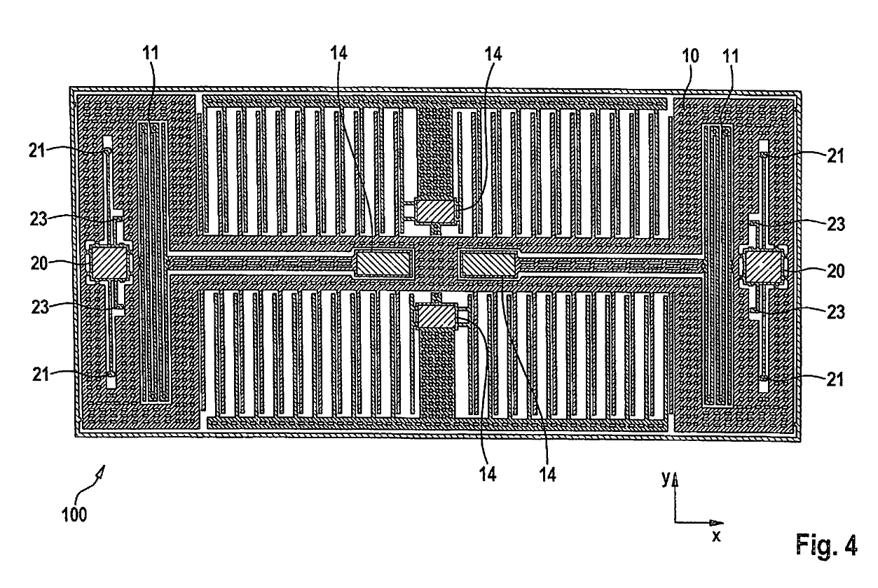

FIG. 4 shows a top view of a complete proposed sensor core 100. It may be seen that second springy stops 23, like first springy stop elements 21, are symmetrically arranged on altogether two stop devices 20 in four edge regions of micromechanical sensor core 100. This creates a symmetry of stop devices 20 having stop elements 21, 22, 23, which distributes the forces of seismic mass 10 efficiently onto springy stop elements 21, 23.

A symmetrical operating behavior and an increased operating reliability of the micromechanical inertial sensor are advantageously supported in this manner.

Advantageously, the provided micromechanical sensor core may be used for any in-plane inertial sensor with a detection of accelerations in the plane.

An impact of a device (e.g., a mobile telephone) equipped with the proposed micromechanical sensor core advantageously has no disadvantageous consequences for the inertial sensor.

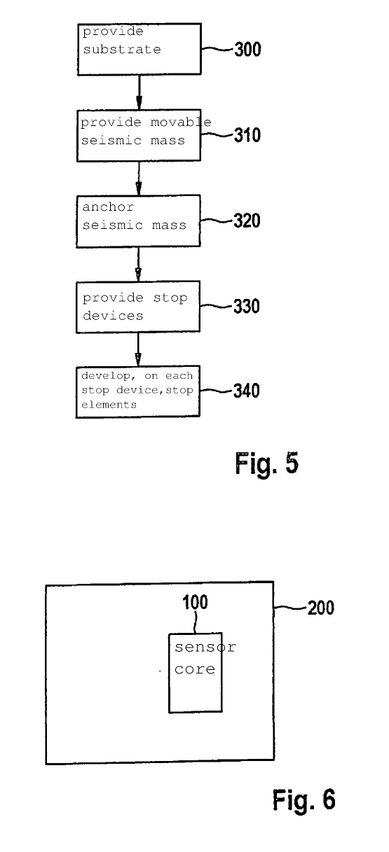

FIG. 5 shows a basic sequence of a specific embodiment for producing a micromechanical inertial sensor.

A substrate is provided in a step 300.

A movable seismic mass is provided in a step 310.

In a step 320, seismic mass 10 is anchored on the substrate by anchor elements 14.

In a step 330, a defined number of stop devices 20 is provided for impacts of seismic mass 10.

In a step 340, a first springy stop element 21, a second springy stop element 23 and a solid stop element 22 are developed on each stop device 20, stop elements 21, 23, 22 being designed in such a way that, in the event of an impact, seismic mass 10 first strikes first springy stop element 21, thereupon second springy stop element 23 and thereupon solid stop element 22.

The sequential order of steps 300 and 310 is arbitrary for this purpose.

FIG. 6 shows a block diagram of an inertial sensor 200 having a proposed micromechanical sensor core 100.

In summary, the present invention provides an improved micromechanical sensor core for an inertial sensor, which achieves a cascading impact behavior of the seismic mass against stop elements and thereby optimizes a return force of the springy stop elements on the seismic mass.

Although the present invention was described above with reference to a concrete exemplary embodiment, it is in no way limited to it. One skilled in the art will recognize that a multitude of variations of the proposed micromechanical sensor core are possible in accordance with the explained principle.

What is claimed is:

1. A micromechanical sensor core for an inertial sensor, comprising:
a movable seismic mass;
a defined number of anchor elements, by which the seismic mass is fastened on a substrate;
a defined number of stop devices fastened on the substrate for stopping the seismic mass; and
a first springy stop element, a second springy stop element and a solid stop element developed on each of the stop devices, wherein the first springy stop element, the second springy stop element, and the solid stop element being designed in such a way that the seismic mass is able to strike in succession against the first springy stop element, the second springy stop element and the solid stop element.

2. The micromechanical sensor core as recited in claim 1, wherein a stiffness of the second springy stop element is greater by a defined measure than a stiffness of the first springy stop element.

3. The micromechanical sensor core as recited in claim 1, wherein per each stop device, respectively two springy first stop elements, two springy second stop elements, and two solid stop elements are developed symmetrically with respect to the seismic mass.

4. The micromechanical sensor core as recited in claim 3, wherein the defined number of stop devices includes two stop devices, which are developed symmetrically with respect to the seismic mass.

5. An inertial sensor having a micromechanical sensor core, the sensor core including a movable seismic mass, a defined number of anchor elements, by which the seismic mass is fastened on a substrate, a defined number of stop devices fastened on the substrate for stopping the seismic mass, and a first springy stop element, a second springy stop element and a solid stop element developed on each of the stop devices, wherein the first springy stop element, the second springy stop element, and the solid stop element being designed in such a way that the seismic mass is able to strike in succession against the first springy stop element, the second springy stop element and the solid stop element.

6. A method for producing a micromechanical sensor core for an inertial sensor, comprising:
providing a substrate;
providing a movable seismic mass;
anchoring the seismic mass on the substrate by anchor elements;
providing a defined number of stop devices for stopping the seismic mass;
developing a first springy stop element, a second springy stop element and a solid stop element on every stop device, the stop elements being designed in such a way that, in the event of an impact, the seismic mass first strikes the first springy stop element, thereupon the second springy stop element, and thereupon the solid stop element.

7. An in-plane inertial sensor, including a micromechanical sensor core, the sensor core including a movable seismic mass, a defined number of anchor elements, by which the seismic mass is fastened on a substrate, a defined number of stop devices fastened on the substrate for stopping the seismic mass, and a first springy stop element, a second springy stop element and a solid stop element developed on each of the stop devices, wherein the first springy stop element, the second springy stop element, and the solid stop element being designed in such a way that the seismic mass is able to strike in succession against the first springy stop element, the second springy stop element and the solid stop element.
